(19) United States
(12) Patent Application Publication
(10) Pub. No.: US 2018/0197962 A1
(43) Pub. Date: Jul. 12, 2018

(54) SEMICONDUCTOR DEVICE

(71) Applicant: Toshiba Memory Corporation, Tokyo (JP)

(72) Inventor: Hiroyoshi Kitahara, Yokohama Kanagawa (JP)

(21) Appl. No.: 15/694,953

(22) Filed: Sep. 4, 2017

(30) Foreign Application Priority Data
Jan. 12, 2017 (JP) 2017-003023

(51) Int. Cl. H01L 29/423; H01L 27/11521; H01L 29/788; H01L 27/11519

(52) U.S. Cl. CPC H01L 29/42324; H01L 27/11519; H01L 29/7885; H01L 27/11521

(57) ABSTRACT

A semiconductor device includes at least one memory cell including a first conductivity type first semiconductor region, a second conductivity type second semiconductor region, which is a source region of the memory cell, over a portion of the first semiconductor region, and a second conductivity type third semiconductor region, which is a drain region of the memory cell, over a portion of the first semiconductor region spaced from the second semiconductor region in a first direction, a gate insulating layer extending over a channel region of the memory cell, which includes a portion of the first semiconductor region between the second and third semiconductor regions, and including a first portion of first thickness and a second portion of second thickness less than the first thickness, an electrically floating gate electrode on the gate insulating layer, and a control gate adjacent to, and spaced from, the electrically floating gate electrode.

### CROSS-REFERENCE TO RELATED APPLICATION

This application is based upon and claims the benefit of priority from Japanese Patent Application No. 2017-003023, filed Jan. 12, 2017, the entire contents of which are incorporated herein by reference.

### FIELD

Embodiments described herein relate generally to a semiconductor device including a logic circuit and a nonvolatile memory.

### BACKGROUND

In a semiconductor device including a logic circuit and a nonvolatile memory, each of the memory cells that constitute the nonvolatile memory has an n-channel MOS transistor structure. A floating gate is provided on a gate insulating film over the channel region of the memory cell between the source region and the drain region thereof. A control gate is located over the floating gate with an inter-gate insulating film therebetween.

Writing data to a memory cell is implemented by injecting hot electrons into the floating gate. Erasing data from the memory cell is implemented by injecting hot holes into the floating gate. To improve the efficiency of the injection of hot electrons and hot holes into the floating gate, the gate insulating film between the floating gate and channel is made thinner. However, as the gate insulating film is made thinner, the data retention capability of the memory cell is degraded.

### DESCRIPTION OF THE DRAWINGS

FIG. 1A is a schematic plan view of a semiconductor device according to a first embodiment of the present disclosure;

FIG. 1B is a cross-sectional view of the semiconductor device of FIG. 1A taken along the line A-A′ of FIG. 1A;

FIG. 1C is a cross-sectional view of the semiconductor device of FIG. 1A taken along the line B-B′ of FIG. 1A;

FIG. 2 is an explanatory diagram for explaining a data write operation for a conventional nonvolatile memory cell;

FIG. 3 is an explanatory diagram for explaining a data erasing operation for the conventional nonvolatile memory cell;

FIG. 4 is a schematic plan view of a semiconductor device according to a second embodiment; and

FIG. 5 is a schematic plan view of a semiconductor device according to a third embodiment.

### DETAILED DESCRIPTION

Embodiments provide a semiconductor device capable of maintaining its data retention capability while also having an increased speed for a data write operation and a data erasing operation for a memory cell in a nonvolatile memory in the semiconductor device.

In general, according to one embodiment, a semiconductor device includes a first conductivity type first semiconductor region, a second conductivity type second semiconductor region over a portion of the first semiconductor region, a second conductivity type third semiconductor region over a portion of the first semiconductor region and spaced from the second semiconductor region in a first direction, a gate insulating layer extending over a channel region, which includes a further portion of the first semiconductor region between the second semiconductor region and the third semiconductor region, the gate insulating layer including at least a first portion having a first thickness and a second portion having a second thickness less than the first thickness, an electrically floating gate electrode on the gate insulating layer, and a control gate adjacent to, and spaced from, the electrically floating gate electrode. The second semiconductor region comprises a source of the memory cell, and the third semiconductor region comprises a drain of the memory cell.

Embodiments of the present disclosure will be described hereinafter with reference to the drawings. The drawings used for description of the embodiments are schematic to be easy to understand, and the shapes, dimensions, magnitude relationships, and the like of constituent elements in an actual implementation are not necessarily identical to those shown in the drawings and can be changed as appropriate in a scope in which the advantages of the present disclosure can be achieved. Constituent elements having similar properties, functions or features are denoted by the same reference numbers or reference signs and a repeated description thereof in the description of a later drawing figure is omitted where appropriate.

### First Embodiment

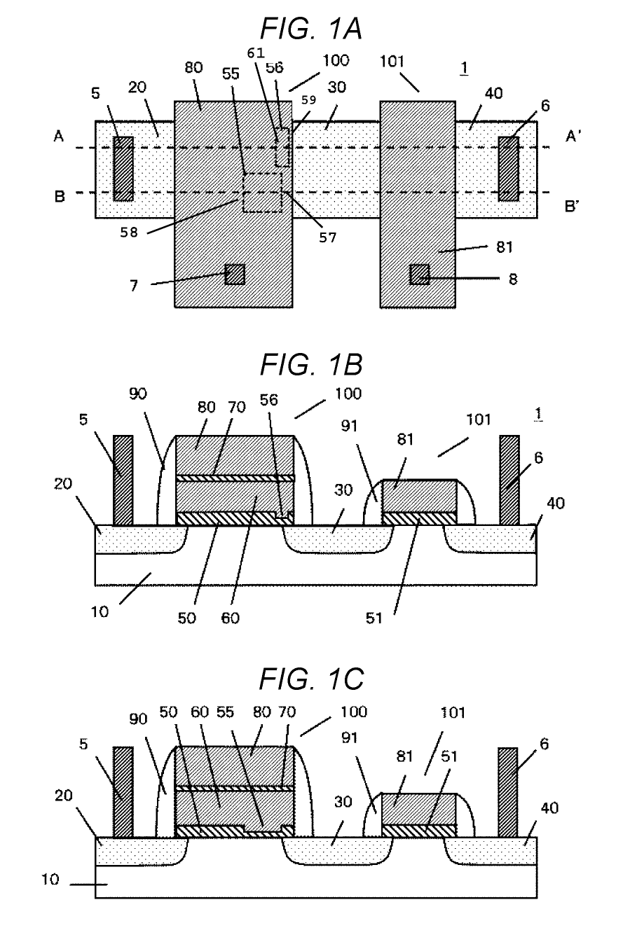

A semiconductor device according to a first embodiment of the present disclosure will be described with reference to FIGS. 1A to 1C. FIG. 1A is a schematic plan view of a memory cell constituting a semiconductor memory in a semiconductor device according to a first embodiment. FIG. 1B is a cross-sectional view of the semiconductor device of FIG. 1A taken along line A-A′ of FIG. 1A and illustrates a memory cell constituting the semiconductor memory in the semiconductor device according to the first embodiment. FIG. 1C is a cross-sectional view of the semiconductor device of FIG. 1A taken along a line B-B′ of FIG. 1A and illustrates a memory cell constituting the semiconductor memory in the semiconductor device according to the first embodiment. It is noted that only the minimum necessary constituent elements for describing a memory cell structure are shown in the figures, and a protective insulating film, interconnect structures and wirings and the like are not shown.

A semiconductor device 1 according to the first embodiment of the present disclosure includes a logic circuit and a nonvolatile semiconductor memory. The nonvolatile semiconductor memory includes memory cells 100. As shown in FIGS. 1A to 1C, each memory cell 100 includes a well region 10 of a first conductivity type, a source region 20 of a second conductivity type, a drain region 30 of the second conductivity type, a gate insulating film 50, a floating gate 60, an inter-gate insulating film 70, and a control gate 80. The memory cell 100 will be described while defining herein that the first conductivity type is a p type and the second conductivity type is an n type. Furthermore, the memory cell 100 will be described herein while defining that the well region 10 is a p-type well region provided on or in a silicon substrate, the source region 20 and the drain region 30 are n-impurity (n-conductivity type) diffusion regions formed in the p-well region 10. However, these definitions are given as an example and the embodiments of the present disclosure are not limited to these definitions.

The n-source region 20 is formed in the p-well region 10. The n-source region 20 extends from a front or uppermost surface of the p-well region 10 inwardly of the p-well region 10. The n-source region 20 is an n-impurity type (n-conductivity type) diffusion region formed by diffusing n-impurities from the front surface of the p-well region 10.

The n-drain region 30 is formed in the p-well region 10. The n-drain region 30 extends from the front or uppermost surface of the p-well region 10 inwardly of the p-well region 10. The n-drain region 30 is an n-impurity type (n-conductivity type) diffusion region formed by diffusing n-impurities from the front surface of the p-well region 10. The n-drain region 30 is provided to be spaced apart from the n-source region 20 in a first direction. In the p-well region 10, the portion thereof sandwiched between the n-source region 20 and the n-drain region 30 forms a channel region. In the channel region, an n-type channel is formed when a voltage equal to or higher than a threshold voltage is applied to the control gate 80 which will be described later herein.

The gate insulating film 50 is located on the channel region. The gate insulating film 50 is located on the channel region of the p-well region 10 in such a manner as to extend over one end of the source region 20 and one end of the drain region 30. The gate insulating film 50 is formed from an insulator and is formed from, for example, silicon oxide. Alternatively, the gate insulating film 50 can be formed from silicon nitride or silicon oxynitride.

The floating gate 60 is located on the gate insulating film 50. The floating gate 60 is formed from, for example, polysilicon; however, a material of the floating gate 60 is not limited to polysilicon. The gate insulating film 50 includes a first recessed portion 55 and a second recessed portion 56 extending into the first surface side thereof which is facing and contacting the floating gate 60, such that a portion of the floating gate 60 extends into the first and second recessed portions 55, 56.

The first recessed portion 55 and the second recessed portion 56 extend inwardly of the gate insulating film 50 from the first surface of the gate insulating film 50 toward the p-well region 10. The gate insulating film 50 is thinner in the first recessed portion 55 and the second recessed portion 56 than in the other portions thereof.

The first recessed portion 55 includes a first end 57, and a second end 58 on the opposite side of the recessed portion 55 from the first end in the first direction. Viewed from the direction perpendicular to the first surface, the first end 57 is located over the channel region between the source region 20 and the drain region 30. The second end 58 is located over the channel region between the source region 20 and the drain region 30. The first end 57 is located closer to the drain region 30 than the second end 58. Furthermore, the second end 58 is preferably closer to the drain region 30 than the midpoint location of the channel region between the source region 20 and the drain region 30 in the first direction (as will be described later herein).

The second recessed portion 56 includes a third end 59 and a fourth end 61 on the opposite side of the recessed portion 55 from the third end in the first direction. The third end 59 is located over the drain region 30 adjacent to the channel region. Alternatively, the third end 59 is located over the drain region 30. The fourth end 61 is provided on the channel region between the source region 20 and the drain region 30. The third end 59 and the fourth end 61 are preferably located such that the second recessed portion extends over the boundary between the drain region 30 and the channel region. In the first direction, the distance between the first end 57 and the second end 58 of the first recessed portion 55 is greater than the distance between the third end 59 and the fourth end 61 of the second recessed portion 56. The material of the floating gate 60 extends inwardly of the first recessed portion 55 and the second recessed portion 56.

The inter-gate insulating film 70 is located on the floating gate 60. The control gate 80 is located over the floating gate 60 with the inter-gate insulating film 70 therebetween. The inter-gate insulating film 70 isolates the floating gate 60 from the control gate 80. The inter-gate insulating film 70 may be formed from an insulator similar to that of the gate insulating film 50 and is formed from, for example, silicon oxide but may be formed from silicon nitride or silicon oxynitride. The control gate 80 is formed from, for example, polysilicon similar to that of the floating gate 60.

A side wall insulating film 90 is provided on the side walls of the gate insulating film 50, the floating gate 60, the inter-gate insulating film 70, and the control gate 80. The floating gate 60 and the control gate 80 are isolated from their surroundings by the side wall insulating film 90.

A select transistor 101 for selecting the memory cell 100 for a reading, writing or erasing operation thereof is located on the p-well region 10. The select transistor 101 includes a source region 30, a drain region 40, a gate insulating film 51, a gate 81, and a side wall insulating film 91. The source region 30 of the select transistor 101 is commonly used as the drain region 30 of the memory cell 100.

The drain region 40 of the select transistor 101 is located in the p-well region 10 and spaced from the source region 30 along the first direction. The drain region 40 is, for example, an n-type-impurity (n-conductivity type) diffusion region similar to the source region 30. In the p-well region 10, the region of the p-well region 10 sandwiched between the source region 30 and the drain region 40 is the channel region, where a channel is formed between the source 30 and drain 40 of the select transistor 101 when a voltage equal to or higher than a threshold voltage is applied to the gate 81.

The gate insulating film 51 is located on the channel region of the p-well region 10 to extend over portions of the source region 30 and the drain region 40 on either side of, and adjacent to, the channel region of the select transistor 101. The gate insulating film 51 may be formed from an insulator similar to that of the gate insulating film 50 of the memory cell 100 and is formed from, for example, silicon oxide or can be formed from silicon nitride or silicon oxynitride.

The gate 81 is located on the gate insulating film 51 over the channel region of the p-well region 10 between the source region 30 and the drain region 40 and the adjacent portions of the source region 30 and the drain region 40. The gate 81 is formed from, for example, polysilicon similar to that of the control gate 80 of the memory cell 100. The side wall insulating film 91 is located on the side walls of the gate insulating film 51 and the gate 81. The gate 81 is isolated from its surroundings by the side wall insulating film 91.

A source electrode 5 is electrically connected to the source region 20 of the memory cell 100. A drain electrode 6 is electrically connected to the drain region 40 of the select transistor 101. A gate electrode 7 is electrically connected to the control gate 80 of the memory cell 100. A gate electrode 8 is electrically connected to the gate 81 of the select transistor 101.

The select transistor 101 is provided to select the memory cell 100 for a reading, writing, or erasing operation thereof. By applying a voltage equal to or higher than a threshold to the gate 81 of the select transistor 101, the memory cell 100 is selected. While the select transistor 101 is provided to select one memory cell 100 in the present embodiment, the number of the memory cells 100 selectable by the select transistor 101 is not limited to one. For example, the select transistor 101 may select a string of a plurality of memory cells 100 connected in series.

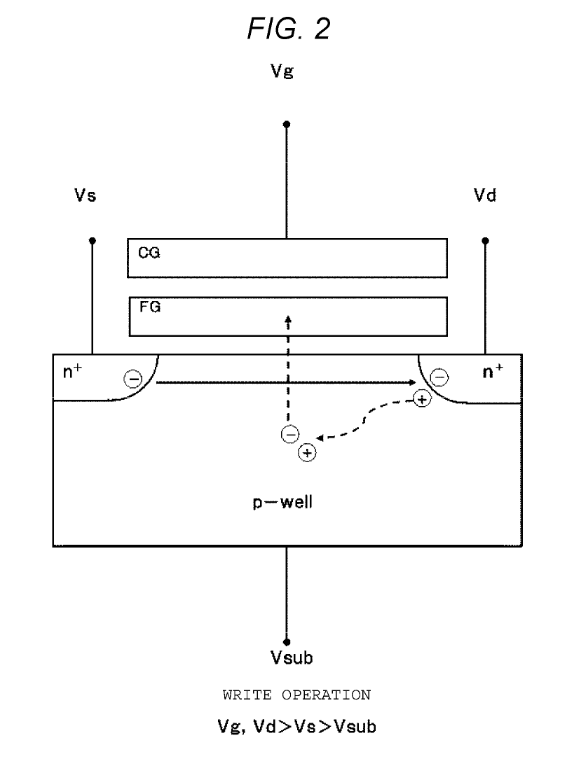

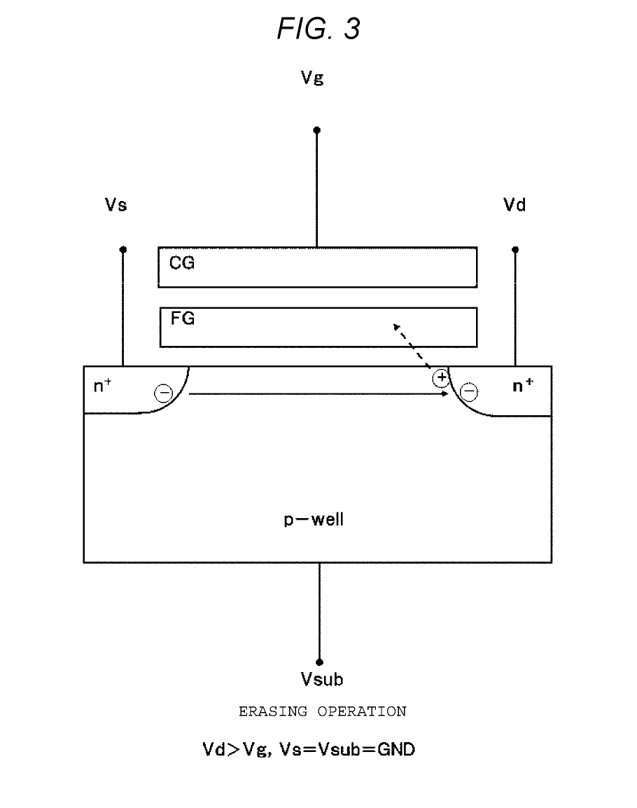

Next, before describing the operations of the memory cell 100 of the semiconductor device 1 according to the present embodiment, the operations of a conventional memory cell will be described with reference to FIGS. 2 and 3. FIGS. 2 and 3 show minimum necessary constituent elements only for ease of the description and understanding. A gate insulating film, an inter-gate insulating film, a side wall film, a protective film, interconnect layers, and wirings and the like are not shown in FIGS. 2 and 3.

FIG. 2 illustrates an operation of writing data to the memory cell. For example, a substrate potential V_{sub} is applied to the p-well region. A source potential Vₛ is applied to the source region. A drain potential V_{d} is applied to the drain region. A gate potential V_{g} is applied to the control gate CG. A floating gate FG is in a state in which no electric charges are accumulated in the floating gate FG and it is electrically neutral, i.e., uncharged.

During the write operation, the substrate potential V_{sub} is, for example, a ground potential (GND). The source potential Vₛ is either equal to the substrate potential V_{sub} or slightly higher than the substrate potential V_{sub}. The drain potential V_{d} is higher than the source potential Vₛ and is, for example, 5V. The gate potential V_{g} is applied to the control gate CG so that the potential of the floating gate FG becomes nearly equal to the drain potential V_{d}. If a coupling ratio of the control gate CG to the floating gate FG is, for example, 0.55, the gate potential V_{g} required to cause the 5V potential to appear on the control gate CG is about 10V (10V×0.55).

If the potential of the floating gate FG is equal to the drain potential V_{d}, electrons travel through a channel from a source toward a drain. The electrons are accelerated by a drain-source voltage to be converted into a high energy state, and impact atoms near the drain, thereby generating electron-hole pairs. Among the electron-hole pairs, holes are accelerated by a high electric field between the source and the drain, and impact atoms in a region where the channel is present, thereby generating hot electrons and hot holes. The hot electrons have high enough energy to cross the insulative barrier of the gate insulating film and are injected into the floating gate FG. The hot holes are discharged from the source region or a back gate of the transistor. This state in which electrons are accumulated in the floating gate FG is a state in which the memory cell retains data.

Referring to FIG. 3, an operation of erasing data from the memory cell will next be described. The ground potential (GND) is applied as the substrate potential V_{sub} and the source potential Vₛ. The drain potential V_{d} of, for example, 5V is applied similarly to that of the write operation. The gate potential V_{g} is applied to the control gate CG so that the potential of the floating gate FG becomes about 1V, far lower than the drain potential V_{d}. If the coupling ratio of the control gate CG to the floating gate FG is, for example, 0.55, the gate potential V_{g} is about 2V (1.0/0.55). The floating gate FG is in a state in which electrons are accumulated.

Similarly to the write operation, electrons impact atoms in a high energy state near the drain as a result of the source to drain voltage difference, thereby generating hot electrons and hot holes. The generated hot holes cross the barrier of the gate insulating film and are injected into the floating gate FG. By injecting the holes into the floating gate FG, the holes are recombined with the accumulated electrons to neutralize the accumulated electrons, and thus the charge state and voltage potential of the floating gate FG. This means that erasure of the data from the memory cell is done and the floating gate has a near 0 or 0 voltage potential. On the other hand, the generated hot electrons are discharged from the drain region of the memory cell.

With the abovementioned method of writing the data in the memory cell by injecting the hot electrons into the floating gate FG and erasing the data by injecting the hot holes into the floating gate FG, to increase the write operation speed and the erasing operation speed of the memory cell it is necessary to make the gate insulating film thinner.

However, with a thinner gate insulating film, the electric charge accumulated in the floating gate FG is liable to leak out through the gate insulating film and the data retention capability of the memory cell is disadvantageously degraded.

According to the present embodiment, the first recessed portion 55 and the second recessed portion 56 are provided in the gate insulating film 50 as shown in FIGS. 1A to 1C. The gate insulating film 50 is thinner at the first recessed portion 55 and the second recessed portion 56 than at the other portions thereof.

As shown in FIG. 2, hot electrons are injected into the floating gate 60 during a write operation. The inventor hereof determined that the hot electrons injected into the floating gate 60 spread in the first direction from the boundary between the drain region 30 and the p-well region 10 toward the source region 20 but minimally spread to the portion of the p-well region adjacent to the source region 20. The inventor realized that it is unnecessary to make the entire gate insulating film 60 uniformly thinner to improve the efficiency of injecting the hot electrons into the floating gate 60.

The first recessed portion 55 in the present embodiment is used when the hot electrons are injected into the floating gate 60. That is, when the potential of the source region 20 is held higher than the substrate potential, and both the potential of the floating gate 60 and the potential of the drain region 30 are brought higher than the potential of the source region 20, for example, equal to or higher than 5V, the hot electrons are injected into the floating gate 60 via the first recessed portion 55. The hot electrons at this time spread from the boundary between the drain region 30 and the p-well region 10 in the channel region to almost the center of the channel region.

Therefore, the first end 57 of the first recessed portion 55 is disposed on the boundary between the drain region 30 and the p-well region 10 or near the boundary thereof in the channel region, accordingly. The second end 58 of the first recessed portion 55 is disposed closer to the source region 20 than the first end 57. The second end 58 is disposed closer to the drain region 30 than the midpoint of the channel region between the source region 20 and the drain region 30. This is because the density of hot electrons becomes lower toward the source region 20 in the first direction as described above.

As described, by providing the first recessed portion 55 in the gate insulating film 50, only the portion of the gate insulating film 50 used when the hot electrons are injected into the floating gate 60 through the gate insulating film 50 is made thin while the portions of the gate insulating film 50 that are not used for the injection of the hot electrons, other than second recessed portion 56, are made thick. With such a configuration, the thin region of the gate insulating film 50 used for injecting the hot electrons into the floating gate 60 is narrow, so that it is possible to suppress leakage of electric charge from the floating gate 60 through the gate insulating film 50. Owing to this, it is possible to maintain the data retention capability of the memory cell 100 according to the present embodiment while increasing the write operation speed.

Next, as shown in FIG. 3, hot holes are injected into the floating gate 60 during an erasing operation. The hot holes injected into the floating gate 60 spread to the portion of the p-well region 10 adjacent to the boundary between the drain region 30 and the p-well region 10 in the channel region in the first direction. That is, the inventor hereof determined that the hot holes spread to the region of the boundary between the p-well region 10 and the drain region 30 from the drain region 30 to the channel region. The inventor hereof thus realized that it is unnecessary to make the entire gate insulating film 60 thinner uniformly for improving efficiency of injecting the hot holes into the floating gate 60.

The second recessed portion 56 in the present embodiment is used when the hot holes are injected into the floating gate 60. That is, when the drain potential V_{d} of, for example, 5V is applied to the drain region 30 and the gate potential V_{g} is applied to the control gate 80 so that the potential of the floating gate 60 is about 1V, which is far lower than the drain potential V_{d}, the hot holes are injected into the floating gate 60 via the second recessed portion 56. The hot holes at this time spread to the area adjacent to the boundary between the p-well region 10 and the drain region 30 from the drain region 30 to the channel region.

Therefore, the third end 59 of the second recessed portion 56 is disposed over the channel region adjacent to the boundary between the drain region 30 and the p-well region 10 or over the drain region 30, accordingly. The fourth end 61 of the second recessed portion 56 is disposed closer to the source region 20 than the third end 59. It is noted that spread of the hot holes in the first direction is narrower than the spread of the hot electrons in the first direction. Furthermore, the hot holes spread into an area of the channel region wherein the far boundary of their spread from the drain region 30 is closer to the drain region 30 than the far boundary of the hot electrons spread from the drain region 30. Owing to this, the distance between the third end 59 and the fourth end 61 of the second recessed portion 56 can be, and is herein, shorter than the distance between the first end 57 and the second end 58 of the first recessed portion 55. Furthermore, the third end 59 is disposed closer to the drain region 30 than the first end 57 in the first direction.

As described, by providing the second recessed portion 56 in the gate insulating film 50, only the portion of the gate insulating film 50 used when the hot holes are injected into the floating gate 60, other than recessed portion 55, is made thin while portions of the gate insulating film 50 that are not used for the injection of the hot holes are made thick. With such a configuration, the thin region of the gate insulating film 50 used for injecting the hot electrons into the floating gate 60 is narrow, so that it is possible to suppress leakage of electric charge from the floating gate 60 through the gate insulating film 50. It is, therefore, possible to maintain the data retention capability of the memory cell 100 while increasing the erasing operation speed.

The total plane areas of the first recessed portion 55 and the second recessed portion 56 are smaller than a plane area of the gate insulating film 50 that covers the channel region, and the first recessed portion 55 and the second recessed portion 56 have less influence on the threshold voltage of the memory cell 100 than does the thicker portions of the gate insulating film 50.

With the above-mentioned configuration, the memory cell 100 constituting the semiconductor memory in the semiconductor device 1 according to the present embodiment can increase the write operation speed and the erasing operation speed while maintaining the data retention capability.

As described, in the present embodiment, the first recessed portion 55 and the second recessed portion 56 are provided in the gate insulating film 50. As shown in FIG. 1A, the first recessed portion 55 and the second recessed portion 56 are spaced apart from each other at least in a second direction perpendicular to the first direction on a surface parallel to a contact surface between the floating gate 60 and the gate insulating film 50.

### Second Embodiment

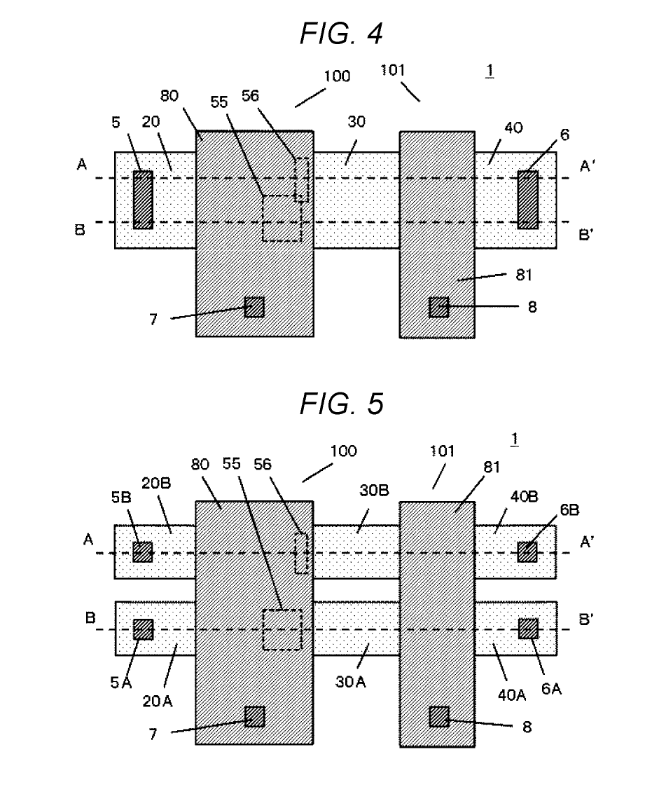

A semiconductor device according to a second embodiment will be described with reference to FIG. 4. Differences from the first embodiment will be mainly described. FIG. 4 is a schematic plan view of a memory cell constituting a semiconductor memory in a semiconductor device according to the present embodiment and corresponds to FIG. 1A illustrating the semiconductor device according to the first embodiment.

The memory cell 100 constituting the semiconductor memory in the semiconductor device 1 according to the present embodiment includes a region where the first recessed portion 55 and the second recessed portion 56 are not spaced apart from each other but overlap each other in the second direction perpendicular to the first direction. That is, there is the portion of the gate insulating layer 50 common to the first recessed portion 55 and the second recessed portion 56. The semiconductor device 1 according to the second embodiment differs from the semiconductor device 1 according to the first embodiment in this respect, while the semiconductor device 1 according to the second embodiment is the same as the semiconductor device 1 according to the first embodiment in other respects.

In the semiconductor device 1 according to the present embodiment, similarly to the semiconductor device 1 according to the first embodiment, the memory cell 100 constituting the semiconductor memory in the semiconductor device 1 has increased writing operation speed and erasing operation speed for the memory cell 100 while it maintains the data retention capability thereof.

### Third Embodiment

A semiconductor device according to a third embodiment will be described with reference to FIG. 5. Differences from the first embodiment will be mainly described. FIG. 5 is a schematic plan view of a memory cell constituting a semiconductor memory in a semiconductor device according to the present embodiment and corresponds to FIG. 1A illustrating the semiconductor device according to the first embodiment.

The semiconductor memory in the semiconductor device 1 according to the present embodiment includes the memory cell 100 that includes source regions 20A and 20B spaced from each other in the second direction and the drain regions 30A and 30B spaced from each other in the second direction, and a select transistor 101 includes drain regions 40A and 40B spaced from each other in the second direction, as opposed to the memory cell 100 that includes the source region 20 and the drain region 30 and the select transistor 101 that includes the drain region 40 according to the first embodiment. The semiconductor device 1 according to the present embodiment differs from the semiconductor device 1 according to the first embodiment in this respect.

That is, the memory cell 100 includes a first channel region sandwiched between the source region 20A and the drain region 30A, and a second channel region sandwiched between the source region 20B and the drain region 30B. The first recessed portion 55 is located in the gate insulating film 50 on the first channel region. The second recessed portion 56 is located in the gate insulating film 50 on the second channel region. The floating gate electrode 60 and the control gate 80 are commonly located on the first and second channel regions.

Likewise, the select transistor 101 includes a first channel region sandwiched between the source region 30A and the drain region 40A, and a second channel region sandwiched between the source region 30B and the drain region 40B. The gate 81 is commonly provided on the first and second channel regions.

The source regions 20A and 20B of the memory cell 100 include source electrodes 5A and 5B, respectively. The drain region 40A and 40B of the select transistor 101 include drain electrodes 6A and 6B, respectively.

In the semiconductor device 1 according to the present embodiment, similarly to the semiconductor device 1 according to the first embodiment, the memory cell 100 constituting the semiconductor memory in the semiconductor device 1 can increase the writing operation speed and the erasing operation speed for the memory cell 100 while maintaining the data retention capability thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising at least one memory cell, wherein said at least one memory cell includes:
a first conductivity type first semiconductor region;
a second conductivity type second semiconductor region over a portion of the first semiconductor region;
a second conductivity type third semiconductor region over a portion of the first semiconductor region and spaced from the second semiconductor region in a first direction, wherein a further portion of the first semiconductor region extends between the second semiconductor region and the third semiconductor region, and the second semiconductor region comprises a source of the memory cell, the third semiconductor region comprises a drain of the memory cell, and the further portion of the first semiconductor region comprises a channel region of the memory cell;
a gate insulating layer extending over the channel region, the gate insulating layer including at least a first portion having a first thickness and a second portion having a second thickness less than the first thickness;
an electrically floating gate electrode on the gate insulating layer; and
a control gate adjacent to, and spaced from, the electrically floating gate electrode.

2. The semiconductor device of claim 1, wherein the second portion of the gate insulating layer extends in the first direction from a location adjacent to the drain of the memory cell to a location over the channel less than midway between the source and the drain of the memory cell.

3. The semiconductor device of claim 2, wherein the gate insulating layer further comprises a third portion having a third thickness less than the first thickness, the third portion of the gate insulating layer disposed in a second direction perpendicular to the first direction from the second portion of the gate insulating layer.

4. The semiconductor device according to claim 3, wherein the third portion of the gate insulating layer is spaced form the second portion of the gate insulating layer in the second direction.

5. The semiconductor device according to claim 3, wherein a part of the third portion of the gate insulating layer overlies the second portion of the gate insulating layer.

6. The semiconductor device according to claim 3, wherein at least a portion of the third portion of the gate insulating layer is closer to the drain of the memory cell than any portion of the second portion of the gate insulating layer.

7. The semiconductor device claim 1, further comprising:
a second conductivity type fourth semiconductor region over a portion of the first semiconductor region, the further semiconductor region spaced from the third semiconductor region by a second further portion of the first semiconductor region;
a selector gate insulating layer located on the second further portion of the first semiconductor region; and
a selector electrode located on the selector gate insulating layer.

8. A semiconductor device comprising a nonvolatile semiconductor memory and a logic circuit, the nonvolatile semiconductor memory including at least one memory cell, which comprises:
a well region of a first conductivity type;
a source region of a second conductivity type in the well region;
a drain region of the second conductivity type in the well region and spaced from the source region by a portion of the first conductivity type well region extending therebetween, said portion of the first conductivity type well region defining a channel region between the source region and the drain region;
a gate insulating film on the channel region;
a floating gate on the gate insulating film and over the channel region and isolated from surrounding portions of the semiconductor device;
an inter-gate insulating film on the floating gate; and
a control gate on the inter-gate insulating film over the floating gate, wherein
the gate insulating film includes a first recessed portion and a second recessed portion.

9. The semiconductor device according to claim 8, wherein
in a first direction from the source region to the drain region, the first recessed portion includes a first end close to the drain region and a second end closer to the source region than the first end, and the second recessed portion includes a third end close to the drain region and a fourth end closer to the source region than the third end;
the distance between the first end and the second end is greater than the distance between the third end and the fourth end;
the first end is closer to the source region than the third end; and
the second end is located over the channel region.

10. The semiconductor device of claim 9, wherein
the third end is located over the drain region; and
the fourth end is located over the channel region.

11. The semiconductor device according to claim 10, wherein the fourth end is between the first end and the second end in the first direction.

12. The semiconductor device according to claim 11, wherein a portion of the first recessed portion overlaps a portion of the second depressed portion.

13. The semiconductor device according to claim 9, wherein the first end and the second end are closer to the drain region than the center of the channel region between the source region and the drain region in the first direction.

14. The semiconductor device according to claim 8, wherein the first recessed portion and the second recessed portion are spaced from each other in a second direction parallel to a contact surface between the gate insulating film and the floating gate and perpendicular to the first direction.

15. The semiconductor device according to claim 14, wherein
the source region includes a first region and a second region spaced from each other in the second direction;
the drain region includes a third region and a fourth region spaced from each other in the second direction;
the first recessed portion is disposed between the first region and the third region; and
the second recessed portion is disposed between the second region and the fourth region, or over the fourth region.

16. A method of maintaining the isolation of a floating gate while increasing the operating speed thereof, comprising:
providing a floating gate structure over a channel located between a source and a drain, the floating gate structure including a gate insulating layer on the channel, a floating gate electrode over the gate insulating layer, an inter-electrode insulating layer over the floating gate electrode, and a control electrode on the inter-electrode insulating layer; and
providing at least a first recess extending inwardly of a surface of the gate insulating layer such that a first portion of the gate insulating layer has a first thickness, and a second portion of the gate insulating layer in the first recess has a second thickness less than the first thickness.

17. The method of claim 16, further comprising:
providing a second recess extending inwardly of a surface of the gate insulating layer such that the first portion of the gate insulating layer has a first thickness, and a third portion of the gate insulating layer in the second recess has a third thickness less than the first thickness.

18. The method of claim 17, wherein the first and second recesses extend inwardly of the gate insulating layer on the floating gate electrode side thereof.

19. The method of claim 17, where the area of the first recess extending inwardly of the gate insulating layer on the floating gate electrode side thereof is greater than the area of the second recess extending inwardly of the gate insulating layer on the floating gate electrode side thereof.

20. The method of claim 17, wherein the first recess extends further toward the source from the drain than does the second recess.
